(19) United States
(12) Patent Application Publication
(10) Pub. No.: US 2009/0236732 A1
(43) Pub. Date: Sep. 24, 2009

(54) THERMALLY-ENHANCED MULTI-HOLE SEMICONDUCTOR PACKAGE

(75) Inventors: Bing-Shun YU, Hukou Shiang (TW); Ching-Wei Hung, Hukou Shiang (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY INC.

(21) Appl. No.: 12/051,429

(22) Filed: Mar. 19, 2008

(51) Int. Cl. H01L 23/367

(52) U.S. Cl. 257/707; 257/E23.102; 257/E23.069

(57) ABSTRACT

A thermal-enhanced multi-hole semiconductor package is revealed, primarily comprising a substrate with a plurality of alignment holes, a chip disposed on the substrate, an internal heat sink attached to the chip, and an encapsulant. The internal hear sink has a plurality of alignment bars and a heat dissipation surface. The alignment bars are inserted into the alignment holes, but not fully occupying the alignment holes to provide a plurality of flowing channels therein. The encapsulant completely encapsulates the alignment bars through filling the flowing channels. Therefore, the internal heat sink can be aligned to the substrate and is integrally connected with the chip and the substrate utilizing a small amount of adhesive or without any adhesive to form a composite having high rigidity and strong adhesion.

### FIELD OF THE INVENTION

The present invention relates to semiconductor devices, especially to thermal-enhanced multi-hole semiconductor packages.

### BACKGROUND OF THE INVENTION

Conventionally, a chip is attached to a substrate and an encapsulant is formed on top of the substrate to encapsulate the chip to avoid external contaminations. As the advances of the semiconductor technologies and the increased functions of IC chips, the operations of an IC chip is faster and faster leading to higher chip temperatures. More and more heat will be cumulated in the encapsulant when the frequencies and the power of IC chip under operations are getting higher and higher. Just by the heat dissipation of chip itself is not enough to transfer the heat to the environment. Therefore, the IC chip inside the encapsulant may be burned by considerable accumulated heat leading to chip failure, package warpage, and component peeling.

As shown in FIG. 1, a conventional window-type semiconductor package 100 comprises a substrate 100, a chip 120, an encapsulant 140, and a plurality of external terminals 160. The substrate 100 has a top surface 111, a bottom surface 112, and a slot 114 penetrating through the substrate 110. The chip 120 has an active surface 121, a back surface 122, and a plurality of bonding pads 123 formed on the active surface 121. The active surface 121 of the chip 120 is attached to the top surface 111 of the substrate 110 with the bonding pads 123 aligned in the slot 114. The bonding pads 123 of the chip 120 are electrically connected to the substrate 110 by a plurality of electrical connecting components 150 such as bonding wires passing through the slot 114. An encapsulant 140 is formed on the top surface 111 of the substrate 110 to encapsulate the chip 120. The external terminals 160 such as solder balls are disposed on the bottom surface 112 of the substrate 110 in a BGA package. There is an internal thermal resistance from the backside of the chip 120 to the top of the encapsulant 140. In order to improve heat dissipation, an external heat spreader is normally disposed on top of the semiconductor package 100 by attaching to the encapsulant 140. However, the internal thermal resistance between the chip 120 and the encapsulant 140 still exists. Moreover, the external heat spreader will increase the thickness and the weight of the semiconductor package. By another conventional solution, an internal heat sink can be disposed inside the semiconductor package between the chip 120 and the encapsulant 140 to increase heat dissipation efficiency. Conventionally, there are two ways of disposing the internal heat sink, the first one is to dispose an internal heat sink on the back surface of the chip before encapsulation, however, the internal heat sink is easily shifted and is exerted an extra internal stress to the chip due to molding pressures, moreover, the internal heat sink is easily delaminated. Two strong adhesive layers are necessary to dispose between the internal heat sink with the chip and between the chip and the substrate. The other way is that the internal heat sink has a chip cavity or a plurality of supporting leads so that the peripheries of the internal heat sink can strongly adhere to the substrate by adhesives or solders. However, when the adhesive is cured or the solder is reflowed, the coplanarity between the heat dissipation surface of the internal heat sink and the top surface of the encapsulant can not be adjusted leading to bleeding of encapsulant onto the heat dissipation surface of the internal heat sink. Furthermore, the encapsulant will flow into and fill the gaps between the internal heat sink and the chip leading to poor thermal conductivity.

### SUMMARY OF THE INVENTION

The main purpose of the present invention is to provide a thermal-enhanced multi-hole semiconductor package by using the alignment bars of an internal heat sink aligned with and inserted into the alignment holes of a substrate. The aligned internal heat sink can be firmly held with a small amount of adhesive or without any adhesive. After packaging processes, the heat dissipation surface of the internal heat sink is free from the contaminations of the encapsulant and there is no gap between the internal heat sink and the chip for filling the encapsulant. The aligned internal heat sink becomes one assembly integrated with the chip and the substrate to enhance the heat dissipation efficiency and to reduce the substrate warpage, moreover, to avoid peeling of the internal heat sink.

The second purpose of the present invention is to provide a thermal-enhanced multi-hole semiconductor package to resolve the issues of shifting of an internal heat sink, extra internal stresses exerted on the chip, and higher heat resistance of an encapsulant.

The third purpose of the present invention is to provide a thermal-enhanced multi-hole semiconductor package to avoid encapsulant bleeding to the exposed heat dissipation surface of the internal heat sink by adjusting the coplanarity between the heat dissipation surface of the internal heat sink and the top surface of the encapsulant.

The fourth purpose of the present invention is to provide a thermal-enhanced multi-hole semiconductor package where the alignment bars of an internal heat sink are fully encapsulated by the encapsulant to provide higher bonding strengths and stronger adhesions with the substrate.

The fifth purpose of the present invention is to provide a thermal-enhanced multi-hole semiconductor package where the internal heat sink is fully adhered to the back surface of a chip to enhance heat dissipation efficiency.

The sixth purpose of the present invention is to provide a thermal-enhanced multi-hole semiconductor package to provide stress buffers between the chip and the substrate.

The seventh purpose of the present invention is to provide a thermal-enhanced multi-hole semiconductor package to enhance the connection between the chip and the substrate to prevent delamination between the chip and the substrate.

According to the present invention, a thermal-enhanced multi-hole semiconductor package is revealed, primarily comprising a substrate, a chip, an internal heat sink, and an encapsulant. The substrate has a top surface, a bottom surface, and a plurality of alignment holes. The chip is disposed on the top surface of the substrate. The internal heat sink disposed on the chip wherein the internal heat sink has a plurality of alignment bars and a heat dissipation surface. The alignment bars are aligned with and inserted into the alignment holes wherein the alignment holes are not fully occupied by the alignment bars to provide a plurality of flowing channels. The encapsulant is formed on the top surface of the substrate to encapsulate the chip and the internal heat sink with the heat dissipation surface exposed. Furthermore, the encapsulant further encapsulates the alignment bars through filling the flowing channels.

### DESCRIPTION OF THE DRAWINGS

FIG. 1 shows a cross-sectional view of a conventional window type semiconductor package.

FIG. 2 shows a cross-sectional view of a thermal-enhanced multi-hole semiconductor package according to the first embodiment of the present invention.

FIG. 3A to 3C show the top surfaces of a substrate of the semiconductor package during manufacturing processes according to the first embodiment of the present invention.

FIG. 4 shows the bottom surface of the substrate before encapsulation according to the first embodiment of the present invention.

FIG. 5 shows a cross-sectional view of the semiconductor package taken along the alignment holes according to the first embodiment of the present invention.

FIG. 6 shows a cross-sectional view of another semiconductor package taken along its alignment holes according to the second embodiment of the present invention.

FIG. 7 shows the top surface of a substrate of the semiconductor package according to the second embodiment of the present invention.

FIG. 8 shows the top surface of the substrate before encapsulation according to the second embodiment of the present invention.

FIG. 9 shows the bottom surface of the substrate before encapsulation according to the second embodiment of the present invention.

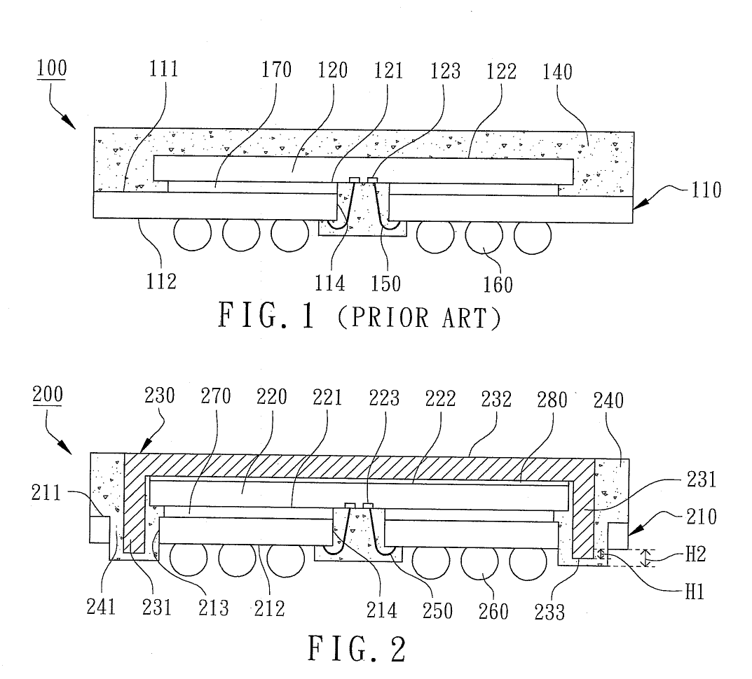

### DETAIL DESCRIPTION OF THE INVENTION

Please refer to the attached drawings, the present invention will be described by means of embodiments below.

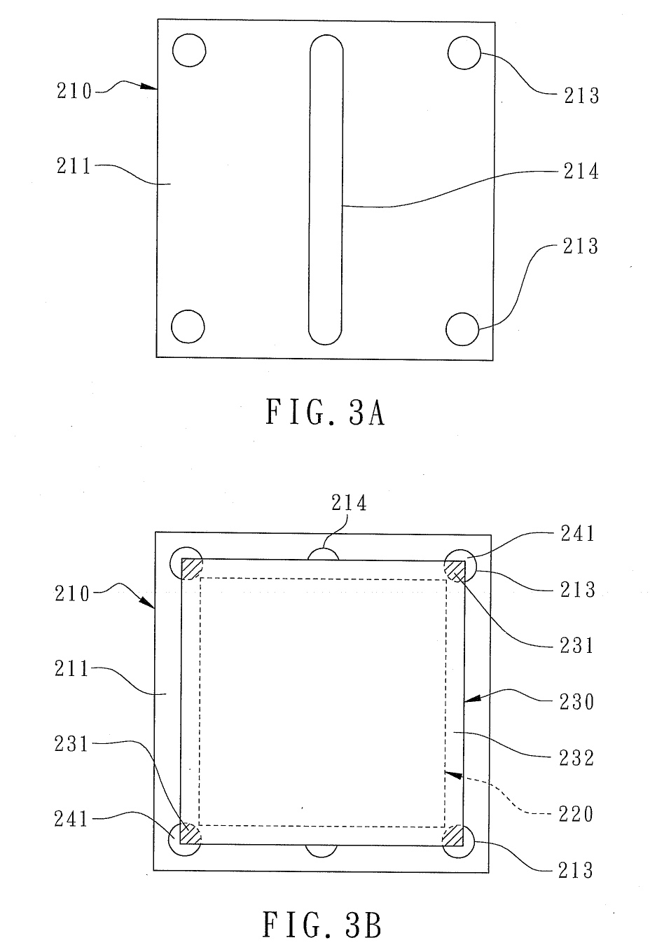

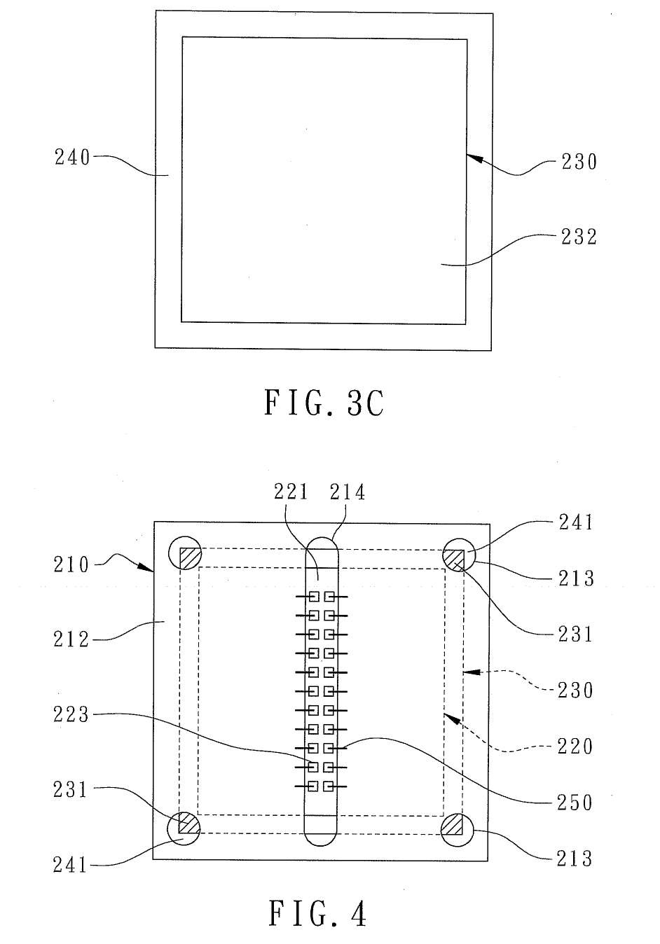

According to the first embodiment of the present invention, as shown in FIG. 2, a thermal-enhanced multi-hole semiconductor package 200 primarily comprises a substrate 210, a chip 220, an internal heat sink 230, and an encapsulant 240. The substrate 210 has a top surface 211, a bottom surface 212, and a plurality of alignment holes 213 where the alignment holes 213 penetrates through the top surface 211 to the bottom surface 212. As shown in FIG. 3A, in the present embodiment, the alignment holes 213 include four corner holes adjacent to the four corners of the substrate 210. The substrate 210 further has a slot 214 located at a central line of the substrate 210. The slot 214 penetrates through the substrate 210 for passing through a plurality of electrical connecting components 250. In this embodiment, the substrate 210 is a printed circuit board including one or more circuit layers.

The chip 220 is attached to the top surface 211 of the substrate 210. As shown in FIG. 3B, both ends of the slot 214 are exposed from the chip 220 to enhance the flowing of the precursor of the encapsulant 240. As shown in FIG. 2, the chip 220 has an active surface 221 and a back surface 222 where a plurality of bonding pads 223 are disposed on the active surface 221 of the chip 220. The chip 220 is attached to the substrate 210 with the active surface 221 faced toward the substrate 210 where the plurality of bonding pads 223 are aligned in the slot 214, as shown in FIG. 4.

As shown in FIG. 2 again, a plurality of electrical connecting components 250, such as bonding wires, pass through the slot 214 and electrically connect the bonding pads 223 of the chip 220 to the bonding fingers of the substrate 210, not shown in the figure. The electrical connecting components 250 are formed by wire bonding.

As shown in FIG. 2 and FIG. 4, an internal heat sink 230 is attached to the back surface 222 of the chip 220 where the internal heat sink 230 has a plurality of alignment bars 231 and a heat dissipation surface 232. The alignment bars 231 are aligned with and inserted into the alignment holes 213 to firmly and accurately hold the internal heat sink 230 on the substrate 210 with a small amount of adhesive or without any adhesive between the internal heat sink 230 and the substrate 210. Moreover, the alignment holes 213 are not fully occupied by the alignment bars 231 to provide a plurality of flowing channels 241 for filling the encapsulant 240. For example, the alignment holes 231 can be round through holes and the alignment bars 231 are not cylindrical. The number of alignment bars 231 is the same as the one of the alignment holes 213. The precursor of the encapsulant 240 can easily flow into the flowing channels 241 so that the encapsulant 240 can encapsulate the alignment bars 231 to firmly and accurately hold the internal heat sink 230. As shown in FIG. 2, preferably, the internal heat sink 230 is smoothly attached to the back surface 222 of the chip 220 by an adhesive layer 280 to avoid the encapsulant 240 bleeding into the gaps between the internal heat sink 230 and the chip 220. Accordingly, heat resistance between the internal heat sink 230 and the chip 220 is minimized. Additionally, the heat dissipation surface 232 of the internal heat sink 230 is free from the contaminations of the encapsulant 240. Heat dissipation efficiency is obviously enhanced. In other words, the internal hear sink 230 is smoothly attached to the back surface 222 of the chip 220 to provide a better support to the chip 220 and to increase the structural strengths of the chip 220 so that the chip 220 will not easily be broken or damaged due to internal stresses leading to electrical open of IC circuits in the chip 220. Therefore, the semiconductor package 200 can package a thinner chips 220 to reduce the overall package heights as well as to avoid chip damages.

To be more specific, the semiconductor package 200 further comprises a buffer layer 270 formed between the chip 220 and the substrate 210 to provide stress buffering between the chip 220 and the substrate 210. In the present embodiment, the buffer layer 270 is a low viscosity elastomer so that the coplanarity between the heat dissipation surface 232 of the internal heat sink 230 and the top surface of the encapsulant 240 can be adjusted during encapsulation. In the present embodiment, the adhesive layer 280 adhering the chip 220 and the internal heat sink 230 to reinforce the adhesions between the chip 220 and the internal heat sink 230. The adhesive layer 280 along with the buffer layer 270 can reduce the internal stresses of the chip 220 and improve thermal mismatched issues between the chip 220 and the substrate 210. Preferably, the adhesions of the buffer layer 270 is smaller than the one of the adhesive layer 280 to enhance the stress buffering effects of the buffer layer 270 without delamination between the chip 220 and the substrate 210.

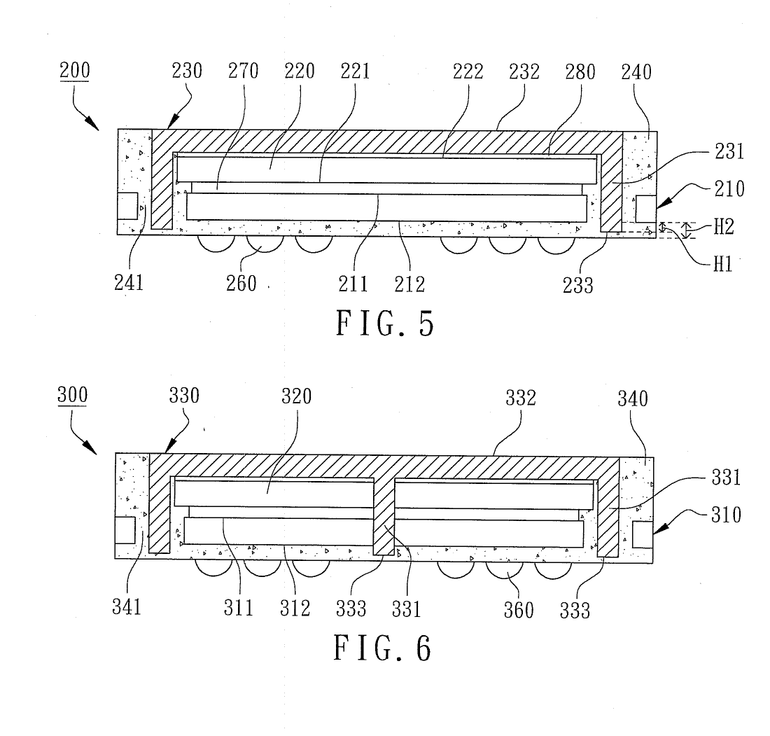

As shown in FIG. 2, the encapsulant 240 is formed on the top surface 211 of the substrate 210 to encapsulate the chip 220 and the internal heat sink 230 with the heat dissipation surface 232 exposed from the top surface of the encapsulant 240 to enhance heat dissipation efficiency. The encapsulant 240 further fills the flowing channels 241 to encapsulate the alignment bars 231 to enhance the structural strengths between the internal heat sink 230 and the substrate 210 to avoid warpage of the substrate 210. As shown in FIG. 2 and FIG. 5, the alignment bars 231 has a plurality of terminals 233 extruded from the bottom surface 212 of the substrate 210 with a first height H1. The encapsulant 240 is extruded from the bottom surface 212 of the substrate 210 with a second height H2 where the second height H2 is larger than the first height H1 to completely encapsulate the terminals 233 of the alignment bars 231 to form an integral chip assembly having high rigidity and strong adhesion and to avoid delaminations between the internal heat sink 230 and the encapsulant 240 due to poor bonding strengths. In the present embodiment, the semiconductor package 200 further comprises a plurality of external terminals 260 such as solder balls disposed on the bottom surface 212 of the substrate 210 where the heights of the external terminals 260 are larger than the one of the second height H2

In summaries, the heat generated by the chip 220 can conduct through the internal heat sink 230 to dissipate the heat to the environment. During semiconductor packaging processes, moreover, the alignment bars 231 of the internal heat sink 230 can be firmly held in the alignment holes 213 of the substrate 210 with a small amount of adhesive or without any adhesive to avoid horizontal shifting of the internal heat sink 230 due to molding pressure. However, the heat dissipation surface 232 of the internal heat sink 230 can be vertically adjusted to be coplanar to the mold cavity of top mold. After semiconductor packaging processes, the alignment bars 231, the encapsulant 240, and the substrate 210 become an integral assembly to avoid peeling of the internal heat sink 230 and the warpage of the substrate 210. Therefore, the internal heat sink 230 can not only provide better heat dissipation paths but also maintain better structural strengths to protect the chip 220 from damages. Therefore, the semiconductor package 200 can resolve the issues of shifting of the internal heat sink, extra internal stresses exerted on the chip, and higher heat resistance of encapsulant.

From FIG. 3A to FIG. 3C, a manufacturing method of the thermal-enhanced multi-hole semiconductor package 200 is described. Firstly, as shown in FIG. 2 and FIG. 3A, a substrate 210 is provided where the substrate 210 has a top surface 211, a bottom surface 212, and a plurality of alignment holes 213. The substrate 210 further has a slot 214 where the alignment holes 213 and the slot 214 penetrate through from the top surface 211 to the bottom surface 212. Then, as shown in FIG. 3B, a chip 220 mentioned above is attached to the top surface 211 of the substrate 210. As shown in FIG. 4, a plurality of bonding pads 223 are aligned within the slot 214 when the active surface 221 of the substrate 220 is attached to the substrate 210. The plurality of electrical connecting components 250 are formed by wire-bonding to electrically connect the bonding pads 223 of the chip 220 to the substrate 210 by passing through the slot 214. Then, as shown in FIGS. 2 and 3B, an internal heat sink 230 mentioned above is attached to the back surface 222 of the chip 220 where the internal heat sink 230 has a plurality of alignment bars 231 and a heat dissipation surface 232. The alignment bars 231 are aligned with and inserted into the alignment holes 213 where the alignment holes 213 are not occupied by the alignment bars 231 to provide a plurality of flowing channels 241. Finally, as shown in FIG. 2 and FIG. 3C, an encapsulant 240 mentioned above is formed on the top surface 211 of the substrate 210 by transfer molding. The encapsulant 240 encapsulates the chip 220 and the internal heat sink 230 with the heat dissipation surface 232 exposed. The encapsulant 240 further fills the flowing channels 241 to encapsulate the alignment bars 231. Therefore, during the manufacturing processes, the internal heat sink 240 can be firmly adhered to the chip 220 and horizontally aligned with the substrate 210. The internal heat sink 240 is also strongly combined with the substrate 210 by the encapsulant 240 using a small amount of adhesive or without any adhesive during semiconductor packaging processes. The processing flow of manufacturing the semiconductor package 200 can be simplified and manufacturing time can be reduced leading to lower manufacturing costs. Moreover, during forming the encapsulant 240, the internal heat sink 230 can slightly adjust in vertical directions to firmly attach to the walls of top mold chest. After encapsulation, the heat dissipation surface 232 of the internal heat sink 230 and the top surface of the encapsulant 240 are in good coplanarity to reduce bleeding of the encapsulant 240 to the exposed heat dissipation surface 232. In the present embodiment, the buffer layer 270 does not firmly adhere the chip 220, therefore, the chip 220 is vertically adjusted during the micro-shifting of the internal heat sink 230.

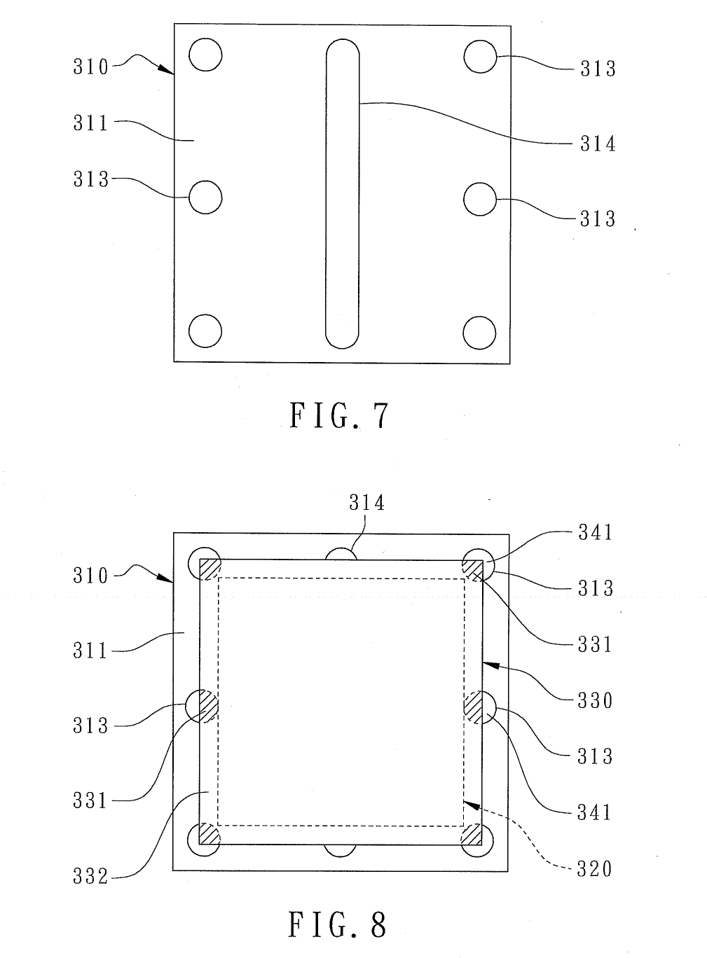

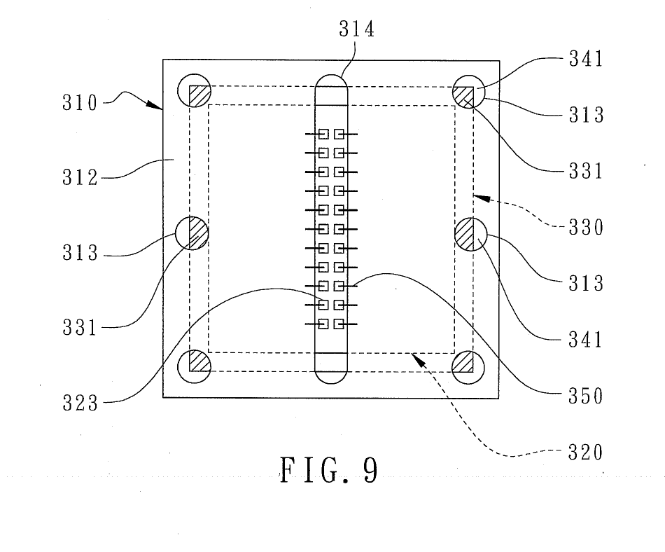

According to the second embodiment of the present invention, another thermal-enhanced multi-hole semiconductor package 200 is revealed. As shown in FIG. 6, the thermal-enhanced multi-hole semiconductor package 300 primarily comprises a substrate 310, a chip 320, an internal heat sink 330 and an encapsulant 240. The substrate 310 has a top surface 311, a bottom surface 312, and a plurality of alignment holes 313. The chip 320 is disposed on the top surface 311 and a plurality of external terminals 360 such as solder balls are disposed on the bottom surface 312 for mounting to an external printed circuit board, not shown in the figure. The alignment holes 313 include four corner holes adjacent to the four corners of the substrate 310. As shown in FIG. 7, in the present embodiment, the alignment holes 313 further include at least two side holes adjacent to the two opposing sides of the substrate 310. As shown in FIG. 8, the chip 320 is attached to the top surface 311 of the substrate 310. As shown in FIG. 9, the chip 320 has a plurality of bonding pads 323 aligned within the slot 314 of the substrate 310. The bonding pads 323 of the chip 320 are electrically connected to the substrate 310 by a plurality of electrical connecting components 350 passing through the slot 314.

As shown in FIG. 6 and FIG. 8, the internal heat sink 330 is attached to the chip 320. The internal heat sink 330 has a plurality of alignment bars 331 and a heat dissipation surface 332 where the alignment bars 331 are aligned with and inserted into the alignment holes 313. The alignment holes 313 are not fully occupied by the alignment bars 331 to provide a plurality of flowing channels. The encapsulant 340 is formed on the top surface 311 of the substrate 310 to encapsulate the chip 320 and the internal heat sink 330 with the heat dissipation surface 332 exposed. The encapsulant 340 further fully fills the flowing channels in the alignment holes 313 to encapsulate the alignment bars 331. As shown in FIG. 6, the alignment bars 331 have a plurality of terminals 333 extruded from the bottom surface 312 of the substrate 310. The encapsulant 340 extrudes from the bottom surface 312 of the substrate 310 to complete encapsulate the terminals 333 of the alignment bars 331 to form high rigidity and strong adhesion with the internal heat sink 330. This combination can avoid peeling between the internal heat sink 330 and the encapsulant 340.

The above description of embodiments of this invention is intended to be illustrative and not limiting. Other embodiments of this invention will be obvious to those skilled in the art in view of the above disclosure.

What is claimed is:

1. A semiconductor package primarily comprising:
a substrate having a top surface, a bottom surface, and a plurality of alignment holes;
a chip disposed on the top surface of the substrate;
an internal heat sink disposed on the chip, wherein the internal heat sink has a plurality of alignment bars and a heat dissipation surface, wherein the alignment bars are aligned with and inserted into the alignment holes, wherein the alignment holes are not fully occupied by the alignment bars to provide a plurality of flowing channels; and
an encapsulant formed on the top surface of the substrate to encapsulate the chip and the internal heat sink with the heat dissipation surface exposed, the encapsulant further encapsulating the alignment bars through filling the flowing channels.

2. The semiconductor package as claimed in claim 1, wherein the alignment bars have a plurality of terminals extruded from the bottom surface of the substrate with a first height, and wherein the encapsulant is extruded from the bottom surface of the substrate with a second height, wherein the second height is larger than the first height to completely encapsulate the terminals.

3. The semiconductor package as claimed in claim 1, wherein the alignment holes includes four corner holes located adjacent to the four corners of the substrate.

4. The semiconductor package as claimed in claim 3, wherein the alignment holes further includes at least two side holes adjacent to two opposing sides of the substrate.

5. The semiconductor package as claimed in claim 1, wherein the chip has an active surface and a back surface with a plurality of bonding pads disposed on the active surface, wherein the bonding pads of the chip are electrically connected to the substrate by a plurality of electrical connecting components.

6. The semiconductor package as claimed in claim 5, wherein the active surface of the chip is attached to the substrate and the internal heat sink is smoothly attached to the back surface of the chip.

7. The semiconductor package as claimed in claim 6, wherein the substrate further has a slot for passing through the electrical connecting components.

8. The semiconductor package as claimed in claim 5, wherein the electrical connecting components include a plurality of bonding wires.

9. The semiconductor package as claimed in claim 1, wherein the alignment holes are round through holes and the alignment bars are not cylindrical.

10. The semiconductor package as claimed in claim 2, further comprising a plurality of external terminals disposed on the bottom surface of the substrate.

11. The semiconductor package as claimed in claim 10, wherein the external terminals include a plurality of solder balls.

12. The semiconductor package as claimed in claim 10, wherein the heights of the external terminals are greater than the second height.

13. The semiconductor package as claimed in claim 1, further comprising a buffer layer disposed between the chip and the substrate.

14. The semiconductor package as claimed in claim 13, wherein the buffer layer is a low viscosity elastomer.

15. The semiconductor package as claimed in claim 13, further comprising an adhesive layer adhering the chip and the internal heat sink.

16. The semiconductor package as claimed in claim 15, wherein the adhesion of the buffer layer is smaller than the one of the adhesive layer.
